(19) United States
(12) Patent Application Publication
(10) Pub. No.: US 2025/0105034 A1
(43) Pub. Date: Mar. 27, 2025

(54) PEDESTAL HEATER

(71) Applicant: Applied Materials, Inc., Santa Clara, CA (US)

(72) Inventors: Justin GAU, Santa Clara, CA (US); Dmitry LUBOMIRSKY, Cupertino, CA (US)

(21) Appl. No.: 18/824,614

(22) Filed: Sep. 4, 2024

Related U.S. Application Data
(60) Provisional application No. 63/540,906, filed on Sep. 27, 2023.

(51) Int. Cl. H01L 21/67; H01L 21/687; H05B 3/22

(52) U.S. Cl. CPC H01L 21/67103; H05B 3/22; H01L 21/68757

(57) ABSTRACT

Disclosed herein are a pedestal heater and processing chamber containing the same. In one example, a pedestal heater for semiconductor substrate processing includes a heater body, a top cover and a bottom cover. The heater body includes at least one heating element. The top cover is disposed on a top surface of the heater body and has a higher thermal conductivity than the heater body. The bottom cover is disposed at a bottom surface of the heater body. In some examples, lift pin holes disposed through the top cover, the heater body and the bottom cover are aligned to accommodate lift pins.

### RELATED APPLICATIONS

This application claims benefit from U.S. Provisional Application Ser. No. 63/540,906, filed Sep. 27, 2023 the contents of which are incorporated herein by reference in its entirety.

### BACKGROUND

### Field

The present disclosure relates to components and apparatus for a semiconductor processing chamber, and more specifically relates to components and apparatus that include a corrosion-resistant pedestal heater.

### Description of the Related Art

Epitaxy refers to processes used to grow a thin crystalline layer (known as an EPI layer) on a crystalline substrate. The EPI layer on a semiconductor substrate can improve the electrical characteristics of the surface and make the substrate and the surface suitable for highly complex microprocessors and memory devices.

Conventional Epi process has challenges meeting lower thermal budget requirements. In addition, Epi chambers require regular cleaning of deposited Si, exposing chamber components, such as the pedestal heaters, to corrosive CI chemistries. Conventional pedestal heaters which are resistant to CI chemistry generally aren't designed to help achieve low thermal budget goals.

Thus, a need exists for an EPI equipment to have an improved pedestal heater.

### SUMMARY

Disclosed herein are a pedestal heater and processing chamber containing the same. In one example, a pedestal heater for semiconductor substrate processing includes a heater body, a top cover and a bottom cover. The heater body includes at least one heating element. The top cover is disposed on a top surface of the heater body and has a higher thermal conductivity than the heater body. The bottom cover is disposed at a bottom surface of the heater body. In some examples, lift pin holes disposed through the top cover, the heater body and the bottom cover are aligned to accommodate lift pins.

In another example, a processing chamber is provided. The processing chamber includes a pedestal heater disposed within a chamber body. The pedestal heater includes a heater body, a top cover, a bottom cover, column support, and a column support cover. The heater body has a disk shape and is fabricated from ceramic. The heater body includes at least one heating element. The top cover is disposed on a top surface of the heater body and has a higher thermal conductivity than the heater body. The bottom cover is disposed at a bottom surface of the heater body. Lift pin holes disposed through the top cover, the heater body and the bottom cover are aligned to accommodate lift pins. The column support is coupled to a bottom of the heater body. The column support cover surrounds the column support and is fabricated from a material more resistant to chlorine than the heater body.

In another example, a pedestal heater includes a heater body comprising a plurality of first lift pin holes; a top cover disposed on a top surface of the heater body and including a plurality of second lift pin holes; and a bottom cover disposed at a bottom surface of the heater body and including a plurality of third lift pin holes. The plurality of the first lift pin holes, the second lift pin holes, and the third lift pin holes are aligned to allow pins to extend therethrough. The top cover and the bottom cover are made of corrosion-resistant materials. The heater body includes resistive heaters configured to heat a substrate. The pedestal heater further includes a gas channel network configured to transfer heat to a peripheral area of the heater body.

In another example, an epitaxial growth apparatus comprises a chamber and a pedestal heater as set forth in the present application.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 illustrates a schematic top view of a processing system, according to an embodiment of the present application.

FIG. 2 illustrates a schematic cross-sectional view of a processing chamber, according to an embodiment of the present application.

FIG. 3 illustrates a schematic perspective view of a pedestal heater, according to an embodiment of the present application.

FIG. 4 illustrates a schematic cross-sectional view of a pedestal heater, according to an embodiment of the present application.

FIG. 5 illustrates a schematic configuration of alignment pins and depressions of a pedestal heater, according to an embodiment of the present application.

FIG. 6 illustrates a coupling configuration among the top cover, the heater body and the bottom cover of a pedestal heater according to an embodiment.

FIG. 7 illustrates a schematic top view of a heater body according to an embodiment.

FIG. 8 illustrates a schematic cross-sectional view of a heater body according to an embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Disclosed herein is a pedestal heater and a processing chamber having the same. Although the pedestal heater is described as used in a processing chamber configured for epitaxial deposition, the pedestal heater may be utilized in other types of semiconductor processing chambers, and for the deposition, treating and/or removal of other types of materials from a semiconductor or other type of work piece. The pedestal heater includes a heater body that uses resistive heaters to heat a substrate via conduction. The resistive heaters may have multiple control zones with electrodes optionally biased by DC and/or RF. The heater body can be made of ceramic aluminum alloys, such as aluminum nitride or aluminum oxide. As aluminum alloys are prone for corrosion by process gases used during EPI growth, such as chlorine containing gases, the heater body is encapsulated by protective covers, such as a top cover, a bottom cover, and a column support cover. The protective covers are made of corrosion-resistant materials, such as quartz and boron nitride (e.g., pyrolytic boron nitride (also known as pyrolytic BN or PBN)), which are compatible with process gases. In an alternative example, a protective coating of boron nitride may be applied directly to the heater body and column support of the pedestal heater. In yet other alternatives, a protective coating of quartz may be applied directly to the heater body and column support of the pedestal heater.

To allow a substrate to be lifted up from the pedestal heater, lift pin holes are provided with the top cover, the bottom cover, and the heater body. The pedestal heater further includes several alignment components to ensure that the lift pin holes are aligned and no slippage occur among covers and the heater body. The pedestal heater further includes a purge flange configured to release purge gas into purge volumes formed inside a column support cover to prevent the seepage of any process gases.

The pedestal heater may also include a gas channel network configured to transfer heat to peripheral areas of a heater body. The gas channel network is disposed under the top cover and allows gases to flow inside the heater body from a gas inlet disposed at a bottom of the pedestal heater to a top surface of the heater body. The gases assist the pedestal heater to provide additional heat to the top cover, which tends to have a relatively lower temperature due to poor heat transfer under vacuum conditions.

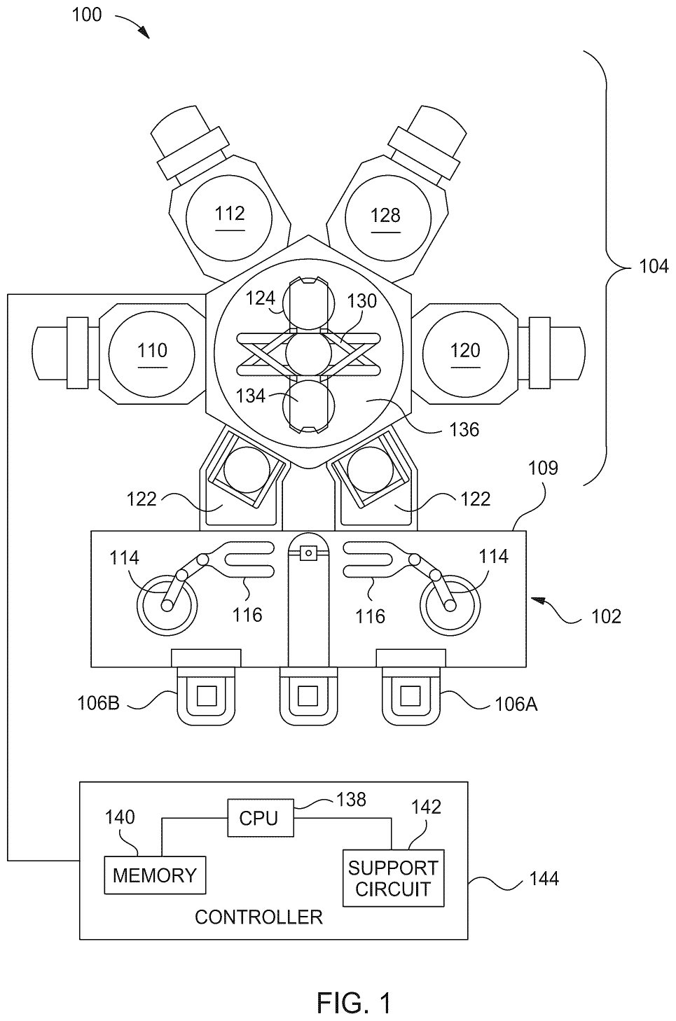

FIG. 1 illustrates a schematic top view of a processing system 100, according to one or more embodiments. The processing system 100 includes one or more load lock chambers 122 (two are shown in FIG. 1), a processing platform 104, a factory interface 102, and a controller 144. In one or more embodiments, the processing system 100 is a CENTURA® integrated processing system, commercially available from Applied Materials, Inc., located in Santa Clara, California. It is contemplated that other processing systems (including those from other manufacturers) may be adapted to benefit from the disclosure.

The platform 104 includes a plurality of processing chambers 110, 112, 120, 128, and the one or more load lock chambers 122 that are coupled to a transfer chamber 136. The transfer chamber 136 can be maintained under vacuum, or can be maintained at an ambient (e.g., atmospheric) pressure. Two load lock chambers 122 are shown in FIG. 1. The factory interface 102 is coupled to the transfer chamber 136 through the load lock chambers 122.

In one or more embodiments, the factory interface 102 includes at least one docking station 109 and at least one factory interface robot 114 to facilitate the transfer of substrates. The docking station 109 is configured to accept one or more front opening unified pods (FOUPs). Two FOUPS 106A, 106B are shown in the implementation of FIG. 1. The factory interface robot 114 having a blade 116 disposed on one end of the robot 114 is configured to transfer one or more substrates from the FOUPS 106A, 106B, through the load lock chambers 122, to the processing platform 104 for processing. Substrates being transferred can be stored at least temporarily in the load lock chambers 122.

Each of the load lock chambers 122 has a first port interfacing with the factory interface 102 and a second port interfacing with the transfer chamber 136. The load lock chambers 122 are coupled to a pressure control system (not shown) which pumps down and vents the load lock chambers 122 to facilitate passing the substrates between the environment (e.g., vacuum environment or ambient environment, such as atmospheric environment) of the transfer chamber 136 and a substantially ambient (e.g., atmospheric) environment of the factory interface 102.

The transfer chamber 136 has a vacuum robot 130 disposed therein. The vacuum robot 130 has one or more blades 134 (two are shown in FIG. 1) capable of transferring the substrates 124 between the load lock chambers 122 and the processing chambers 110, 112, 120, and 128.

The controller 144 is coupled to the processing system 100 and is used to control processes and methods, such as the operations of the methods described herein (for example the operations of the method 1000 and/or the method 1050 described below). The controller 144 includes a central processing unit (CPU) 138, a memory 140 containing instructions, and support circuits 142 for the CPU. The controller 144 controls various items directly, or via other computers and/or controllers.

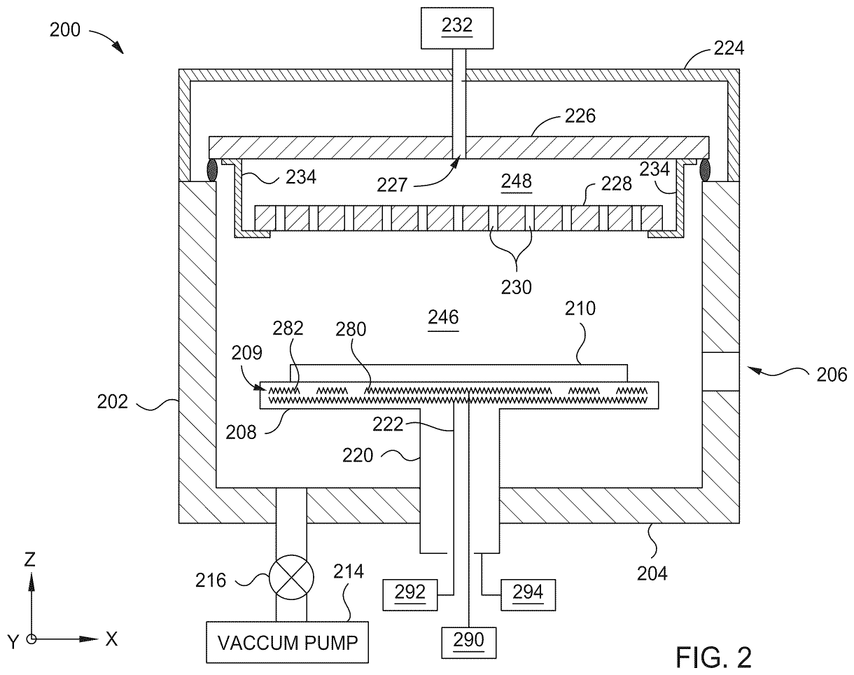

FIG. 2 illustrates a schematic cross-sectional view of an EPI processing chamber 200 according to an embodiment. The processing chamber 200 may be any one of the processing chambers 110, 112, 128, and 120 as shown in FIG. 1. The EPI processing chamber 200 in FIG. 2 includes walls 202, a bottom 204, and a chamber lid 224, which enclose a processing region 246 and a substrate 210 disposed on a pedestal heater 220. The wall 202 includes a plurality of ports 206 for transferring the substrate 210 in or out of the EPI processing chamber 200. According to an embodiment, the pedestal heater 220 is configured to heat the substrate 210 via conduction.

The pedestal heater 220 may be a resistive heater that includes heating elements 209 in the heater body 208 of the pedestal heater 220. The heating elements 209 are connective with heater controller 290 via electrical leads 222. The heating elements 209 may be configured as a single mesh electrode, or be segmented into various independently controllable heating zones. In one example, the heating elements 209 includes an inner electrode 280 that is surrounded by one or more outer electrodes 282. In other examples, the heating elements 209 may be arranged in an independently addressable rid of electrodes. In the example depicted in FIG. 2, the heating elements 209 includes an inner electrode 280 that is surrounded by one or more concentric ring-shaped outer electrodes 282. As each electrode 280, 282 are separately coupled to the heater controller 290, the amount of heat generated by each electrode 280, 282 can be independently controlled, resulting in edge to center temperature zone control of the heater 220, and ultimately, the substrate 210 processed thereon.

The pedestal heater 220 may optionally be biased with RF and/or DC power. The RF and/or DC bias may be provided to the mesh/electrodes comprising the heating elements 209. Alternatively and as illustrated in FIG. 2, the pedestal heater 220 includes a bias electrode 284 coupled to a bias power source 292. The bias power source 292 may be selected to provide RF and/or DC power to the bias electrode 284. Although the bias electrode 284 is shown below the heater electrode 209, the bias electrode 284 may alternatively be located between the heater electrode 209 and the top surface of the heater body 208.

The pedestal heater 220 is also coupled to a purge gas source 294. The purge gas source 294 generally provides an inert gas, such as nitrogen, into the interstitial space defined between the pedestal heater component to prevent process gases from entering the pedestal heater 220 can creating corrosion issues.

According to an embodiment, the external surface of the pedestal heater 220 is encapsulated with corrosion-resistant material to prevent the internal parts of the pedestal heater 220 from being corroded. The corrosion-resistant material may include any suitable materials that are compatible with chlorine containing gases, such as boron nitride or quartz. According to an embodiment, the pedestal heater 220 is coupled with a lift (not shown), such as a motor, configured to raise or lower the pedestal heater 220 within the EPI processing chamber 200.

The EPI processing chamber 200 further includes a vacuum pump 214, and a gas source 232. The vacuum pump 214 is coupled to the EPI processing chamber 200 and is configured to adjust the vacuum level via a throttle valve 216. Vacuum pump 214 evacuates EPI processing chamber 200 prior to substrate processing. The gas source 232 provides process gases into a gas plenum 248 via an outlet 227 formed through a support plate 226. A gas distribution showerhead 228 is attached to the support plate 226 by an adapter 234 to uniformly distribute the process gases from the plenum 248 to the processing region 246. In an embodiment, the gas distribution showerhead 228 may be coupled to the wall 202. The gas distribution showerhead 228 includes a plurality of apertures 230 arranged in a predetermined pattern that are configured to distribute the process gas evenly within the processing region 246. In an embodiment, the process gas may be additionally introduced into processing region 246 via inlets and/or nozzles (not shown) that are attached to walls 202 in addition to or in lieu of gas distribution showerhead 228.

A deposition process is generally performed by raising the temperature of the pedestal heater 220 and the substrate 210 to a predetermined temperature. Then, one or more gases from the gas source 232 are introduced into the processing region 246 of the EPI processing chamber 200. The precursor gas or gases in processing region 246 may be energized (e.g., excited) into a plasma state. The excited gas reaches to the surface of the substrate 210 and then reacts to form a layer of crystalline material on the surface of substrate 210.

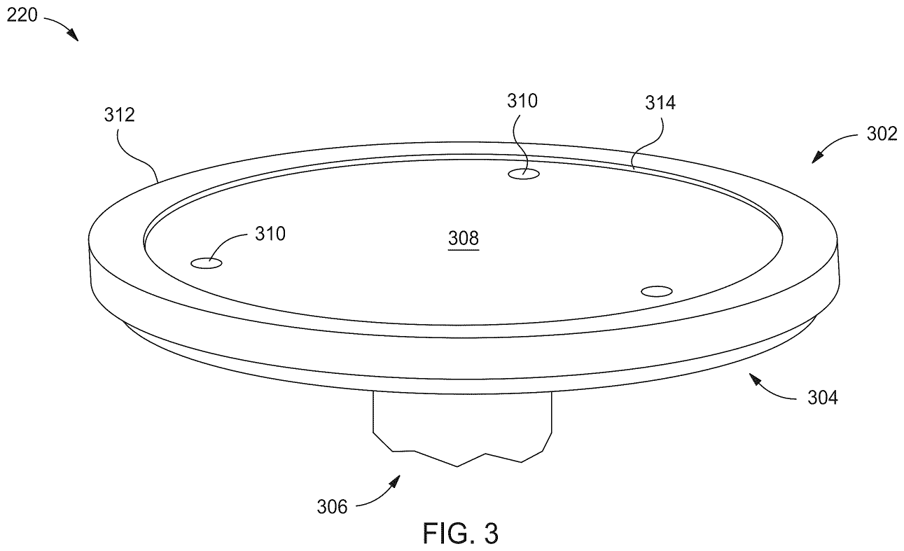

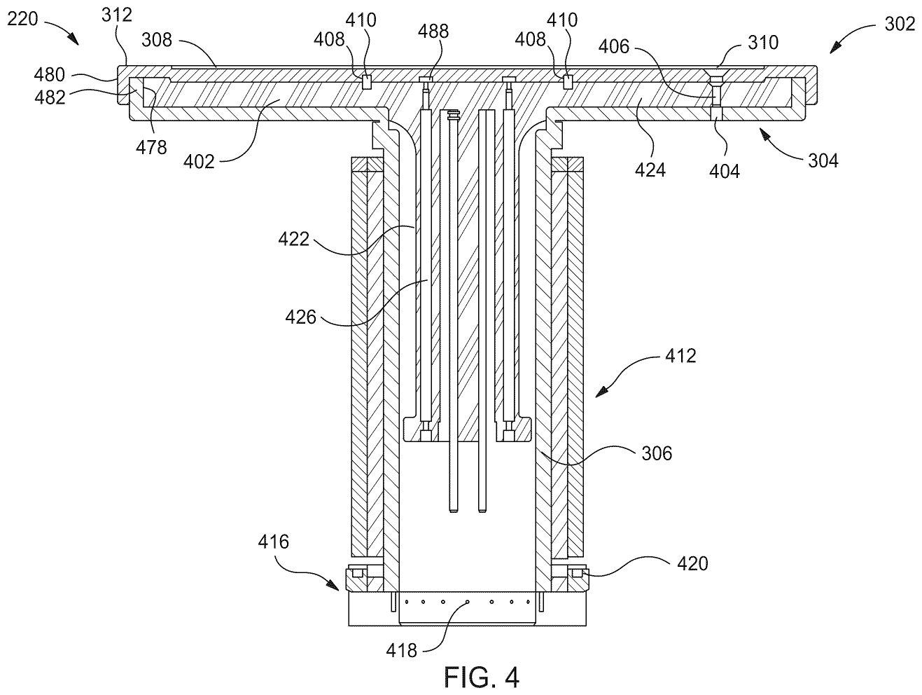

FIG. 3 illustrates a schematic perspective view of the pedestal heater 220, according to an embodiment. The pedestal heater 220 a heater body (402 shown in FIG. 4) coupled to a column support (422 shown in FIG. 4). The heater body and column support are covered by a top cover 302, a bottom cover 304, a column support cover 306. The heater body and the support column may be made of materials desirable for heaters, but are prone to corrosion by certain process gas. In an example, the heater body and the support column are made of aluminum nitride or aluminum oxide (Alumina). To protect the heater body and the support column, the top cover 302, the bottom cover 304 and the column support cover 306 are made of materials resistant to process gases as plasmas formed from the same, such as chlorine gas, chlorine containing gas mixtures or chlorine containing plasmas. In one example, the top cover 302, the bottom cover 304 and the column support cover 306 are made of boron nitride, such as pyrolytic boron nitride (also known as pyrolytic BN or PBN). The top cover 302, the bottom cover 304, and the column support cover 306 are configured to encapsulate substantially all surfaces of the heater body and the support column to protect the body and column from corrosion by process gases. According to an embodiment, the top cover 302 contacts with the substrate 210 during processing within the processing chamber, and has a higher thermal conductivity relative to the heater body 402. The boron nitride (or other material such as quartz) material of the top cover 302 may be arranged such that the thermal conductivity is greater in the horizontal plane relative to the vertical direction (as defined by the vertical/central axis of the column support 422/column support cover 306. The bottom cover 304 is configured to reduce thermal loss and has a low thermal conductivity. According to an embodiment, the top cover 302 is configured to have a higher thermal conductivity than the bottom cover 304. In another example, the bottom cover 304 has a higher thermal conductivity relative to the heater body 402.

As shown in FIG. 3, the top cover 302 includes an edge region 312 and a recessed substrate pocket 308. The substrate pocket 308 has a shape similar to that of the substrate 210 and is configured to support the substrate 210 during processing. In one example, the recessed substrate pocket 308 has a cylindrical shape, while in another example, the recessed substrate pocket 308 has a retangular or box-line shape. The edge region 312 has a ring shape and is disposed around the perimeter area of the pedestal heater 220. The edge region 312 surrounds the substrate pocket 308 and prevents the substrate 210 from slippage during processing. A slanted wall 314 is disposed between the edge region 312 and the substrate pocket 308. The slanted wall 314 may flares outward from the recessed substrate pocket 308 to the edge region 312. The top cover 302 further includes a plurality of lift pin holes 310 disposed within the substrate pocket 308. After deposition, a plurality of lift pins (not shown) may extend through the plurality of lift pin holes 310 from the bottom to lift the substrate 210 above the pedestal heater 220 for transferring.

FIG. 4 illustrates a schematic cross-sectional view of the pedestal heater 220. As shown in FIGS. 3 and 4, a heater body 402 is covered by the top cover 302 and the bottom cover 304, and a column support 422 is covered by the column support cover 306. According to an embodiment, the heater body 402 is substantially T-shaped comprises of a horizontal cap 424 coupled with the column support 422. The cap 424 may be disk-shaped, rectangular, or have another suitable geometry. A downturned skirt 480 of the top cover 302 and a upturned rim 482 of the bottom cover 304 overlay each other covering an outer diameter edge 478 of the heater body 402 to avoid exposing the heater body 402 to the process gases. The top cover 302, the bottom cover 304, and the heater body 402 include a plurality of lift pin holes 310, 404, and 406, respectively. The lift pin holes 310, 404, and 406 are aligned with each other to allow lift pins to pass therethrough. According to an embodiment, one or more alignment pins 408 are disposed between the top cover 302 and top surface of the heater body 402 to maintain the relative position between the cover 302 and body 402. The alignment pins 408 may be fabricated from the same material of the heater body 402 to avoid CTE mismatch issues. In one example, the alignment pins 408 are connected to the top cover 302 and the heater body 402 includes a plurality of alignment depressions 410 configured to receive the alignment pins 408. The alignment pins 408 and depression 410 are configured to align lift pin holes 310 in the top cover and the lift pin holes 406 in the heater body 402. According to an embodiment, alignment pins are also disposed in the bottom cover 304. Although not shown in FIG. 4, the heater body 402 includes the resistive heaters (209 shown in FIG. 2).

The column support 422 is protected by the column support cover 306 which is also made of a corrosion-resistant material, such as a chlorine-resistant material. The column support 422 and the column support cover 306 are coupled with each other coaxially in a manner that allows purge gas provided by the purge gas source (294 shown in FIG. 2) to fill the interstitial space defined between the column support 422 and the column support cover 306, and the interstitial space defined between the heater body 402 and the covers 302, 304. The purge gas present in the interstitial spaces between the body 402/column support 422 and the covers 302, 304, 306 prevent process gases from reaching the heater body 402 through the interfaces between the covers 302, 304, 306. For example, the column support cover 306 overlaps with the bottom cover 304 to prevent process gas from contacting the heater body 402.

During operation, the column support cover 306 and the heater body 402 may be lifted together. Thus, a sleeve 412 attached to the chamber wall 202 is included to provide a conduit to guide the movement of the column support cover 306 and the heater body 402. In one example, the column support cover 306 includes a bottom flange 420 that engages with an end of the sleeve 412 to form a gas tight seal when the column support cover 306 is lifted up. The bottom flange 420 may include a groove. According to another embodiment, the column support cover 306 also includes a bottom purge flange 416 having a plurality of gas inlets 418. The plurality of gas inlets 418 are configured to flow purge gas from the purge gas source (294 shown in FIG. 2) to the space or volume inside the column support cover 306. The purge gas creates a positive pressure inside the column support cover 306, which can prevent process gas from entering the inside of the column support cover 306 and corroding the heater body 402.

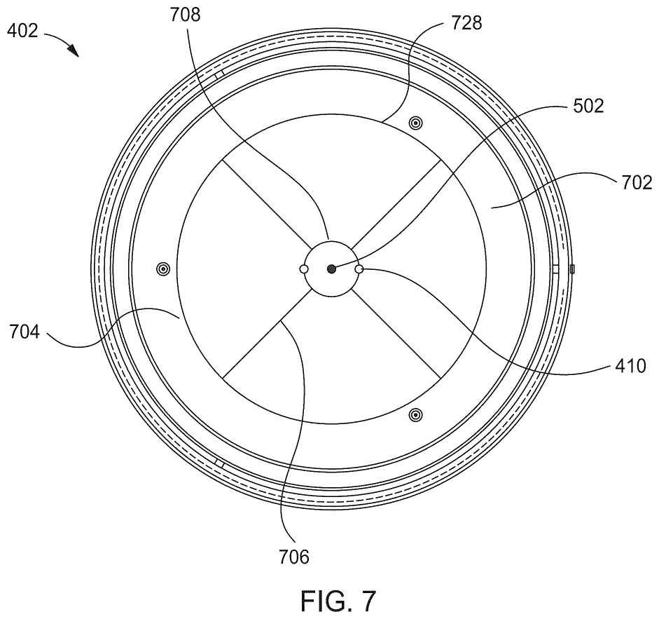

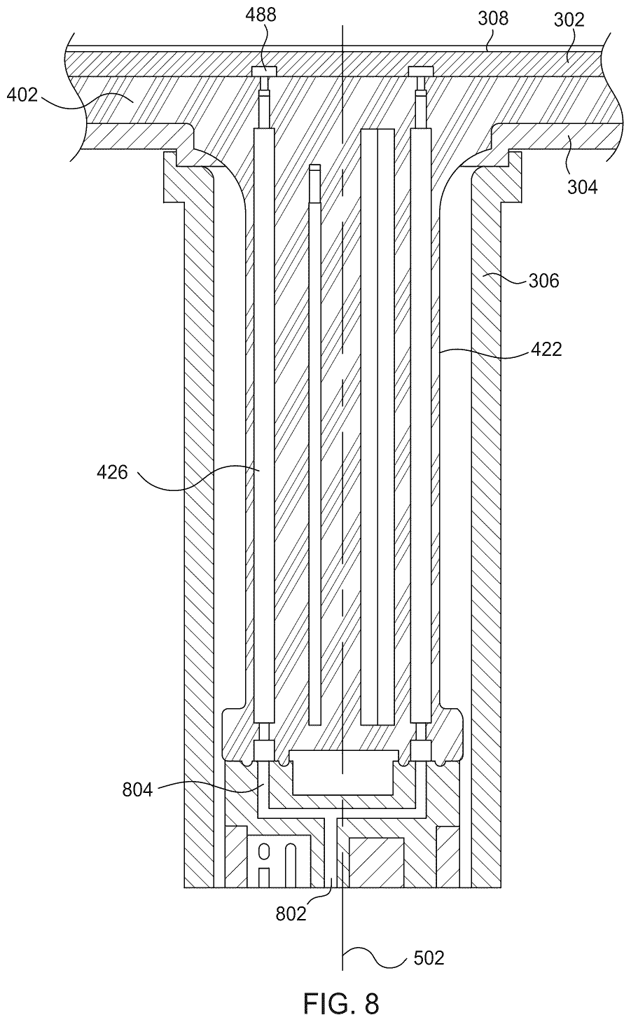

In an example, the heater body 402 optionally includes a gas channel network configured to improve the temperature profile of the top cover 320. The channel network includes a plurality of gas channels 426 disposed in the column support 422 coupled to a plurality of gas channels 728 disposed on a top surface 702 (728, 702 are shown in FIG. 7) of the heater body 402. The plurality of channels 426 and 728 couple with each other via the channels 488 formed in a bottom of the top cover 302. The plurality of channels 426, 488 and 728 are configured to provide gases from the gas inlets 418 to the top surface of the heater body 402. The gases can allow better heat transfer from the heater body 402 to the top cover 302, and thus, better temperature control of the substrate being processed on the pedestal heater 220. A more detailed description of the channel network will be provided later in this specification with references to FIGS. 7 and 8.

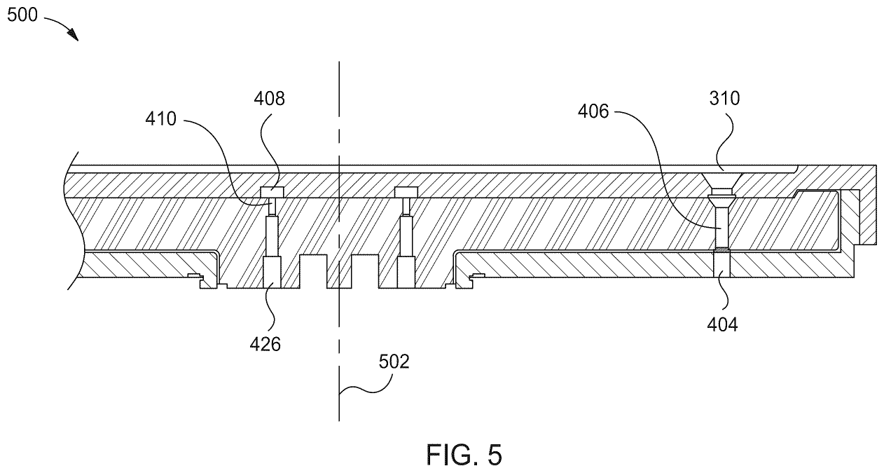

FIG. 5 illustrates a schematic configuration showing an alignment configuration for lift pin holes of a pedestal heater 220 according to an embodiment. To ensure that the lift pin holes 310, 406, 404 provide efficient movement of the lift pins and accurate alignment, additional configurations are provided to quickly and accurately align the lift pin holes. As shown in FIG. 5, a plurality of alignment pins 408 are disposed at the bottom surface of the top cover. According to an embodiment, the alignment pins 408 are disposed symmetrically around a central axis of the pedestal heater 220. A plurality of alignment apertures 410 are disposed at the top surface of the heater body that are configured to receive the alignment pins. The alignment pins 408 and the alignment apertures 410 are manufactured with high precision such that when they engage with each other, the lift pin holes 310, 406, and 404 are accurately aligned. In one example, the alignment pins 408 are fabricated form the same material as the heater body 402 to minimize CTE mismatching.

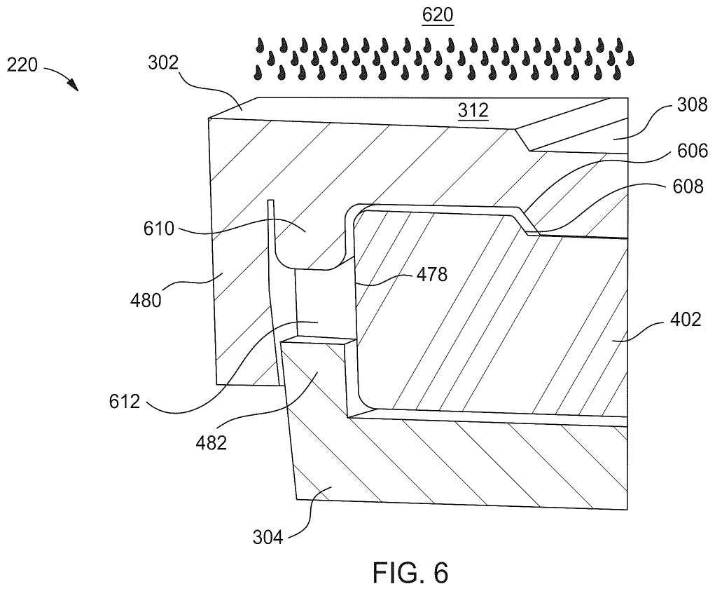

FIG. 6 illustrates a schematic configuration among the top cover, the heater body and the bottom cover of a pedestal heater 220 according to an embodiment. The configuration represents a peripheral zone of the pedestal heater 220 where the bottom cover 304, the heater body 402, and the top cover 302 meet each other. As the process gas 620 fans downward from the showerhead 228 to the pedestal heater 220, the top cover 302 includes a skirt 480 that extends downward from the bottom of the edge region 312 and covers (i.e., overlaps) a rim 482 extending upward from the bottom cover 304 such that the process gas 620 does not easily flow into gaps between the top cover 302 and the bottom cover 304. In FIG. 6, the skirt 480 overlaps the outside of the rim 482 The skirt 480 and the rim 482 have substantial overlap to protect the outside diameter edge 478 of the heater body 402 sandwiched between the top cover and the bottom cover.

According to an embodiment, the pedestal heater 220 includes several designs to retain the top cover 302 on the heater body 402. In one example, the heater body 402 includes a slanted wall 608 disposed at the top surface. A slanted wall 606 is disposed at the bottom surface of the top cover 302. The two slanted walls 608 and 606 have complimentary angles that align with each other to prevent slippage of the top cover 302 off of the heater body 402. In another example, the skirt 480 (or other portion of the top cover 302) further includes a plurality of tabs 610 that engage with slots 612 formed on the upward facing edge of the rim 482. In another example, the skirt 480 may include the slots 612 while the rim 482 may include the mating tabs 610.

FIG. 7 illustrates a schematic top view of the heater body 402 according to an embodiment. The plurality of channels 728 are disposed on the top surface 702 of the heater body 402. In one embodiment, the plurality of channels 728 are configured to transfer inert gases, such as helium gas or any other suitable gases, to the peripheral areas of the heater body 402 to maintain a constant rate of heat transfer across the entire heater surface. The plurality of channels include inner channels 708, branch channels 706, and peripheral channels 704. The inner channels 708 couple with the channels 488 formed in a bottom of the top cover 302 and are configured to distribute the gases from the channels 488 to the branch channels 706. The branch channels 706 are configured to provide the gases from the inner channels 708 to the peripheral channels 704 that cover a substantially amount of peripheral areas. In one example, the inner channels 708 form a circle around the axis 502 of the heater body 402. The branch channels 706 are straight channels configured to lower the resistance when gases are delivered from inner channels to the peripheral channels. The peripheral channels 704 also form a circle that is coaxial with the inner channels 708.

FIG. 8 illustrates a schematic cross-sectional view of the heater body 402. A main channel 802 is coupled with a gas inlet (418 shown in FIG. 4) and a branch channel 804. Gases flow from the gas inlet 418 to the main channel 802 and then to the branch channel 804, which distributes the gases to the gas channels 426. In one embodiment, the main channel 802 is parallel with the axis 502 of the heater body 402. The branch channel 804 is disposed orthogonal to the main channel 802. The gas channels 426 are parallel with the axis 502 of the heater body 402.

It is contemplated that one or more aspects disclosed herein may be combined. Moreover, it is contemplated that one or more aspects disclosed herein may include some or all of the aforementioned benefits. While the foregoing is directed to embodiments of the present disclosure, other and further embodiments of the disclosure may be devised without departing from the basic scope thereof, and the scope thereof is determined by the claims that follow.

What is claimed is:

1. A pedestal heater for semiconductor substrate processing, the pedestal heater comprising:
a heater body comprising at least one heating element, the heater body having a central axis extending normally through the heater body;
a top cover disposed on a top surface of the heater body, the top cover having a higher thermal conductivity than the heater body; and
a bottom cover disposed at a bottom surface of the heater body.

2. The pedestal heater according to claim 1, wherein the at least one heating element comprises a plurality of concentric and independently controllable heating elements.

3. The pedestal heater according to claim 1, wherein the top cover has a higher thermal conductivity than the bottom cover.

4. The pedestal heater according to claim 1, wherein the top cover and the bottom cover are made of boron nitride.

5. The pedestal heater according to claim 1, wherein the top cover has a thermal conductivity is greater in a plane defined normal to the central axis relative to a direction normal to the plane.

6. The pedestal heater according to claim 1 further comprising:
a plurality of first gas channels disposed on a top surface of the heater body.

7. The pedestal heater according to claim 1 further comprising:
alignment pins engaging the top cover and the heater body.

8. The pedestal heater according to claim 1, wherein the top cover and bottom cover have tabs engaged in slots.

9. The pedestal heater according to claim 1, wherein the top cover comprises:
a skirt extending downward and overlapping with a rim of the bottom cover.

10. The pedestal heater according to claim 9, wherein the skirt of the top cover and the rim of bottom cover have tabs engaged in slots.

11. The pedestal heater according to claim 1, further comprising:
a column support coupled to a bottom of the heater body; and
a column support cover surrounding the column support.

12. The pedestal heater according to claim 11, wherein the column support cover is made from boron nitride or quartz and the column support is made from ceramic.

13. The pedestal heater according to claim 11, further comprising:
plurality of gas inlets configured to direct purge gas between the column support cover and the column support.

14. The pedestal heater according to claim 1, further comprising:
a bias electrode disposed in the heater body.

15. A processing chamber comprising:
a chamber body; and
a pedestal heater disposed within the chamber body and comprising:
a heater body fabricated from ceramic, the heater body comprising at least one heating element and a plurality of first lift pin holes, the heater body having a central axis extending normally through the heater body;
a top cover disposed on a top surface of the heater body and comprising a plurality of second lift pin holes, the top cover having a higher thermal conductivity than the heater body;
a bottom cover disposed at a bottom surface of the heater body and comprising a plurality of third lift pin holes configured to align with the plurality of the first lift pin holes and the plurality of the second lift pin holes;
a column support coupled to a bottom of the heater body; and
a column support cover surrounding the column support, the column support cover fabricated from a material more resistant to chlorine than the heater body.

16. The processing chamber according to claim 15, wherein the at least one heating element comprises a plurality of concentric and independently controllable heating elements.

17. The processing chamber according to claim 15, wherein the top cover and the bottom cover are made of boron nitride or quartz, and the heater body is fabricated from Alumina or aluminum nitride.

18. The processing chamber according to claim 15, wherein the top cover has a thermal conductivity that is greater in a plane defined normal to the central axis relative to a direction normal to the plane.

19. The pedestal heater according to claim 15, wherein the pedestal heater further comprising:
a gas inlet configured to direct purge gas between the column support cover and the column support.

20. The pedestal heater according to claim 15, wherein the heater body further comprises:
a bias electrode disposed in the heater body.
